(19) United States
(12) Patent Application Publication
(10) Pub. No.: US 2024/0014108 A1
(43) Pub. Date: Jan. 11, 2024

(54) SEMICONDUCTOR DEVICE

(71) Applicant: ROHM CO., LTD., Kyoto-shi (JP)

(72) Inventors: Satoki TANIGUCHI, Kyoto-shi (JP); Kentaro NASU, Kyoto-shi (JP); Yoshiaki OCHI, Kyoto-shi (JP)

(21) Appl. No.: 18/474,796

(22) Filed: Sep. 26, 2023

Related U.S. Application Data
(63) Continuation of application No. PCT/JP2022/010283, filed on Mar. 9, 2022.

(30) Foreign Application Priority Data
Mar. 30, 2021 (JP) 2021-056341

(51) Int. Cl. H01L 23/495; H01L 23/31; H01L 29/866

(52) U.S. Cl. CPC H01L 23/49562; H01L 23/49575; H01L 23/3107; H01L 29/866; H01L 2224/48137; H01L 24/48

(57) ABSTRACT

A semiconductor device includes a first lead, a second lead spaced apart from the first lead in a first direction, a first semiconductor element on the first lead, a second semiconductor element on the second lead, and a sealing resin covering the first lead, the second lead, the first semiconductor element and the second semiconductor element. The first and second semiconductor elements respectively have first and second element side surfaces facing with each other in the first direction. The sealing resin has a first-direction middle plane equidistant from the first and the second element side surfaces in the first direction. The first lead includes a first main part, and the second lead includes a second main part. The first and the second main parts are spaced apart from each other with reference to the first-direction middle plane.

### TECHNICAL FIELD

The present disclosure relates to semiconductor devices.

### BACKGROUND ART

For semiconductor devices built with semiconductor elements, various configurations have been proposed. JP-A-2020-88035 discloses an example of a conventional semiconductor device. The semiconductor device disclosed in JP-A-2020-88035 includes a plurality of leads, a semiconductor element and a sealing resin. The semiconductor element (6) is mounted on one of the leads (3). The other leads (1 and 2) than the one lead (3) are spaced apart from the one lead (3) in a direction orthogonal to the thickness direction (z) of the one lead (3). The sealing resin (8) covers a part of each lead and the semiconductor element and has a rectangular shape as viewed in the thickness direction (z).

The semiconductor device disclosed in JP-A-2020-88035 is for surface mounting on a circuit board of a various types of devices. During operation of the semiconductor device, heat and other factors may cause warping of the circuit board that supports the semiconductor device. Warping of the circuit board will exert a stress on the sealing resin and/or the leads. When undue stress is applied to the region of the sealing resin corresponding to the gap between the leads that are spaced apart in the direction x, the sealing resin can be detached from the leads or can develop cracks.

### BRIEF DESCRIPTION OF THE DRAWINGS

FIG. 1 is a perspective view of a semiconductor device according to a first embodiment of the present disclosure.

FIG. 2 is a perspective view of the semiconductor device according to the first embodiment of the present disclosure (with a sealing resin shown as transparent).

FIG. 3 is a plan view of the semiconductor device shown in FIG. 1 (with the sealing resin shown as transparent).

FIG. 4 is a bottom view of the semiconductor device shown in FIG. 1.

FIG. 5 is a front view of the semiconductor device shown in FIG. 1.

FIG. 6 is a right-side view of the semiconductor device shown in FIG. 1.

FIG. 7 is a sectional view taken along line VII-VII of FIG. 3.

FIG. 8 is a sectional view taken along line VIII-VIII of FIG. 3.

FIG. 9 is a sectional view taken along line IX-IX of FIG. 3.

FIG. 10 is a diagram showing a circuit configuration of the semiconductor device according to the first embodiment of the present disclosure.

FIG. 11 is a sectional view in which the semiconductor device shown in FIG. 1 is mounted on a circuit board, showing the section corresponding to FIG. 7.

FIG. 12 is a plan view, similar to FIG. 3, of a semiconductor device according to a first variation of the first embodiment.

FIG. 13 is a front view of the semiconductor device shown in FIG. 12.

FIG. 14 is a plan view, similar to FIG. 3, of a semiconductor device according to a second variation of the first embodiment.

FIG. 15 is a front view of the semiconductor device shown in FIG. 14.

FIG. 16 is a plan view, similar to FIG. 3, of a semiconductor device according to a third variation of the first embodiment.

FIG. 17 is a front view of the semiconductor device shown in FIG. 16.

FIG. 18 is a plan view, similar to FIG. 3, of a semiconductor device according to a fourth variation of the first embodiment.

FIG. 19 is a front view of the semiconductor device shown in FIG. 18.

FIG. 20 is a plan view, similar to FIG. 3, of a semiconductor device according to a fifth variation of the first embodiment.

FIG. 21 is a front view of the semiconductor device shown in FIG. 20.

### DETAILED DESCRIPTION OF EMBODIMENTS

The following describes preferred embodiments of the present disclosure with reference to the drawings.

In the description of the present disclosure, terms such as “first”, “second”, “third” and so on are used merely as labels and are not intended to limit the orders of the objects to which the terms refer.

In the description of the present disclosure, the expression “an object A is formed in an object B”, and “an object A is formed on an object B” imply the situation where, unless otherwise specifically noted, “the object A is formed directly in or on the object B”, and “the object A is formed in or on the object B, with something else interposed between the object A and the object B”. Likewise, the expression “an object A is arranged in an object B”, and “an object A is arranged on an object B” imply the situation where, unless otherwise specifically noted, “the object A is arranged directly in or on the object B”, and “the object A is arranged in or on the object B, with something else interposed between the object A and the object B”. Further, the expression “an object A is located on an object B” implies the situation where, unless otherwise specifically noted, “the object A is located on the object B, in contact with the object B”, and “the object A is located on the object B, with something else interposed between the object A and the object B”. Still further, the expression “an object A overlaps with an object B as viewed in a certain direction” implies the situation where, unless otherwise specifically noted, “the object A overlaps with the entirety of the object B”, and “the object A overlaps with a part of the object B”.

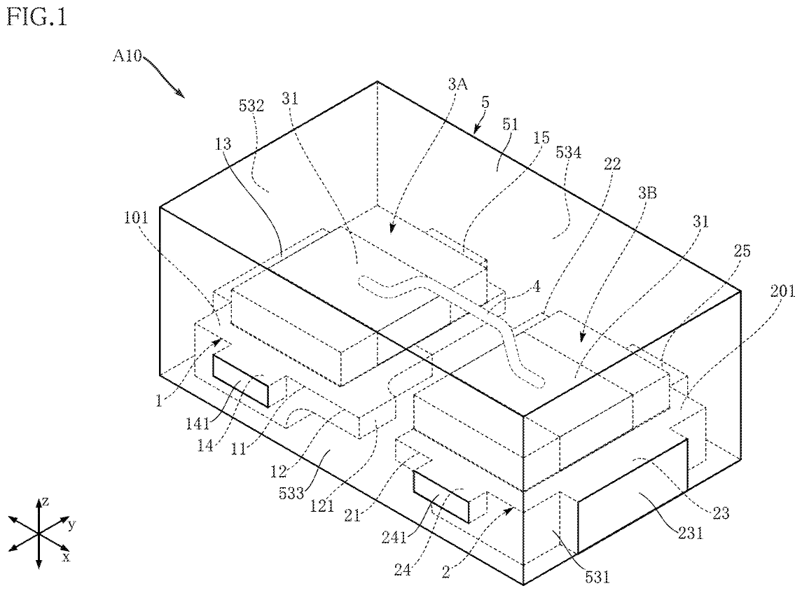

FIGS. 1 to 11 show a semiconductor device according to a first embodiment of the present disclosure. The semiconductor device A10 of the present embodiment includes a first lead 1, a second lead 2, a first semiconductor element 3A, a second semiconductor element 3B, a conducting member 4 and a sealing resin 5. As shown in FIG. 1, the semiconductor device A10 is provided in a QFN (Quad For Non-Lead) package.

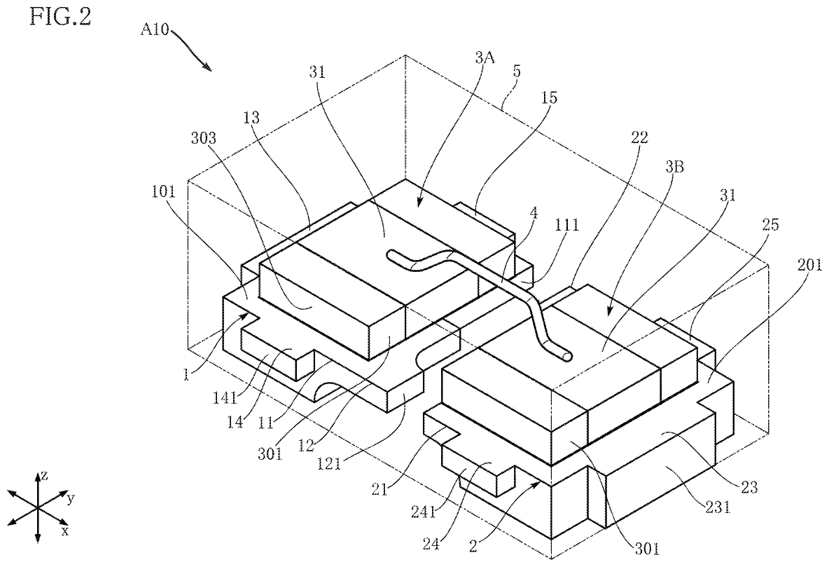

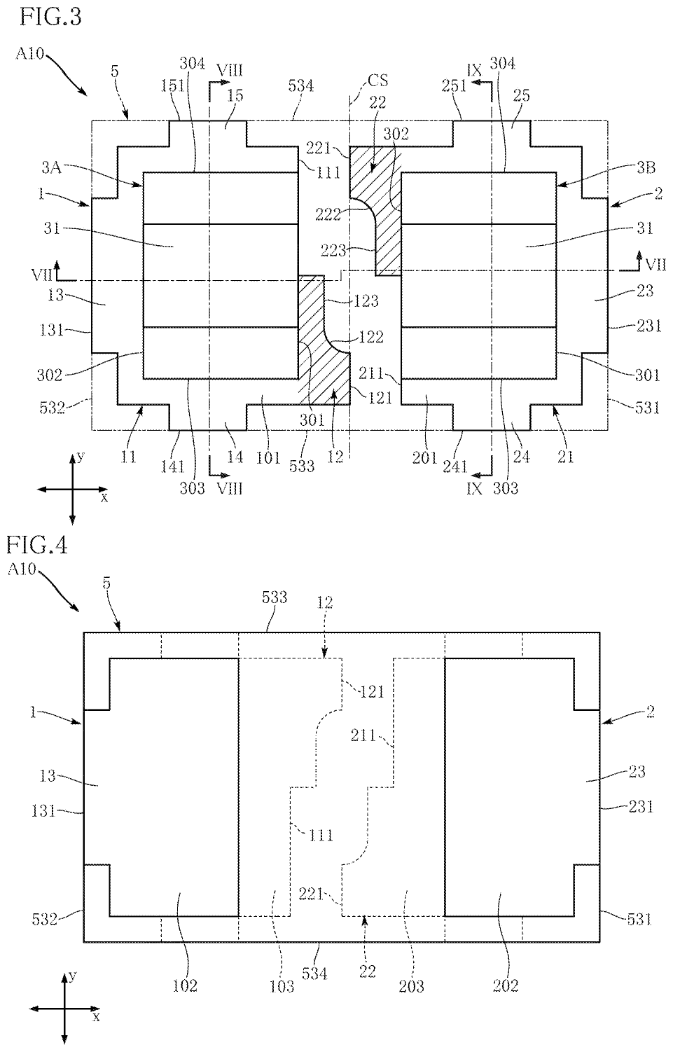

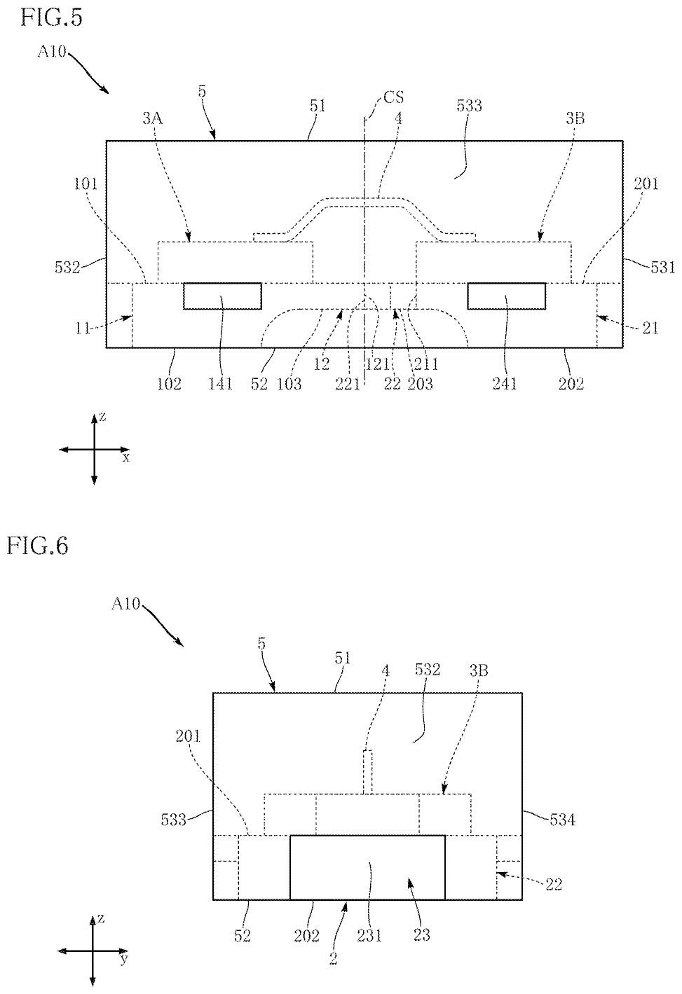

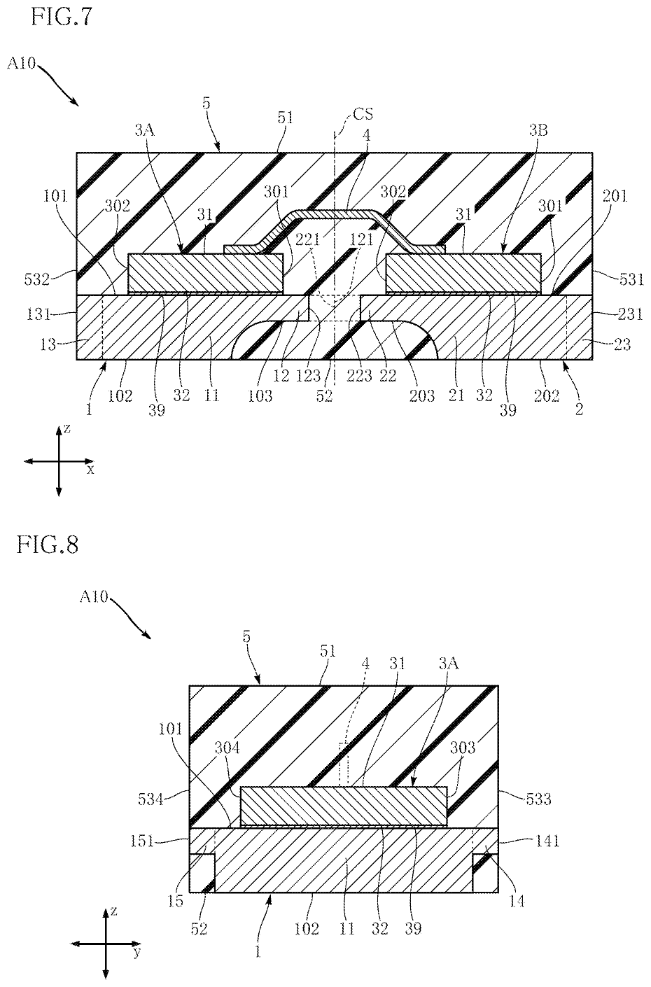

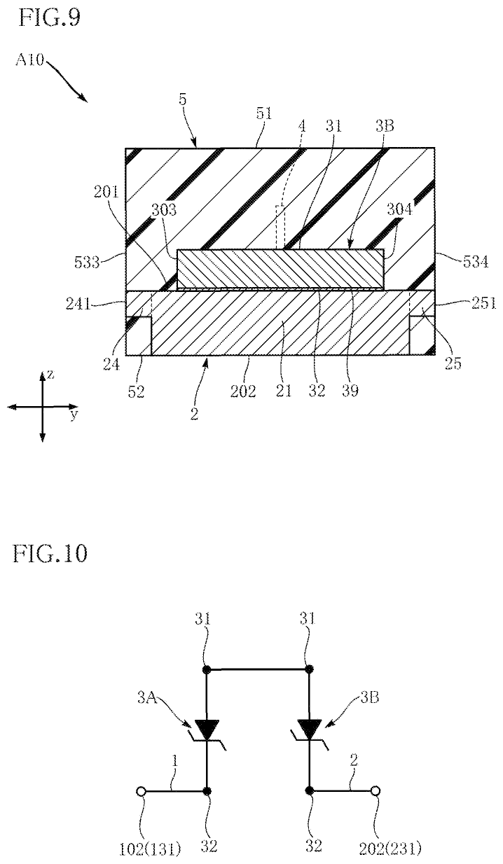

FIG. 1 is a perspective view of the semiconductor device A10. FIG. 2 is a perspective view of the semiconductor device A10. FIG. 3 is a plan view of the semiconductor device A10. FIG. 4 is a bottom view of the semiconductor device A10. FIG. 5 is a front view of the semiconductor device A10. FIG. 6 is a right-side view of the semiconductor device A10. FIG. 7 is a sectional view taken along line VII-VII of FIG. 3. FIG. 8 is a sectional view taken along line VIII-VIII of FIG. 3. FIG. 9 is a sectional view taken along line IX-IX of FIG. 3. For the convenience of description, FIGS. 2 and 3 show the sealing resin 5 as transparent. In these figures, the sealing resin 5 is indicated by imaginary lines (two-dot-dash lines). In FIG. 3, in addition, the conducting member 4 is omitted.

The semiconductor device A10 shown in the figures is for surface mounting on a circuit board of a various devices. The semiconductor device A10 is rectangular as viewed in the thickness direction. In the description of the semiconductor device A10, the thickness direction of the semiconductor device A10 is designated as a “thickness direction z”. A direction orthogonal to the thickness direction z and parallel to one edge of the semiconductor device A10 (the horizontal direction in FIG. 3) is designated as a “first direction x”. The direction orthogonal to both the thickness direction z and the first direction x (the vertical direction in FIG. 3) is designated as a “second direction y”. The size of the semiconductor device A10 is not particularly limited. In the present embodiment, the semiconductor device A10 may measure about 0.4 to 8.0 mm in the first direction x, about 0.2 to 8.0 mm in the second direction y, and about 0.15 to 1.0 mm in the thickness direction z.

The first lead 1 and the second lead 2 may be formed from a metal plate by punching and etching, for example. The first lead 1 and the second lead 2 are made of a material such as copper (Cu), nickel (Ni) or an alloy of such a metal. Each of the first lead 1 and the second lead 2 is partly covered with the sealing resin 5.

In FIG. 3, the first lead 1 is located on the left part of the semiconductor device A10 (offset in a second sense of the first direction x), and the second lead 2 is located on the right part of the semiconductor device A10 (offset in a first sense of the first direction x). The first lead 1 and the second lead 2 are spaced apart from each other in the first direction x.

As shown in FIGS. 3 to 5, 7 and 8, the first lead 1 includes a first obverse surface 101, a first reverse surface 102 and a first recessed surface 103. The first obverse surface 101 faces in a first sense of the thickness direction z. The first obverse surface 101 is covered with the sealing resin 5. Each of the first reverse surface 102 and the first recessed surface 103 faces away from the first obverse surface 101 (faces in a second sense of the thickness direction z). The first reverse surface 102 is exposed from the sealing resin 5. The first recessed surface 103 is offset from the first reverse surface 102 in the first sense of the thickness direction z and hence closer than the first reverse surface 102 to the first obverse surface 101. As viewed in the thickness direction z, the first recessed surface 103 overlaps with a part of the first obverse surface 101. As viewed in the thickness direction z, the first recessed surface 103 is offset in the first sense of the first direction x from the first reverse surface 102. The first recessed surface 103 is covered with the sealing resin 5. The first recessed surface 103 is formed by half-etching, for example.

The first lead 1 includes a first main part 11, a first extending part 12, a first terminal part 13, a first connecting part 14 and a second connecting part 15. As shown in FIG. 3, the first main part 11 is rectangular as viewed in the thickness direction z. In FIG. 3, the first main part 11 is located on the left side (offset in the second sense of the first direction x) with respect to the center of the semiconductor device A10 in the first direction x.

As shown in FIGS. 3 to 5 and 7, the first main part 11 includes a part of the first obverse surface 101, a part of the first reverse surface 102, a part of the first recessed surface 103 and a first inner surface 111. The first obverse surface 101 corresponding to the first main part 11 is where the first semiconductor element 3A is mounted. The first reverse surface 102 corresponding to the first main part 11 serves as a reverse-surface terminal. The first inner surface 111 is located at the end of the first main part 11 in the first sense of the first direction x and faces in the first sense of the first direction x. The first inner surface 111 is connected to both the first obverse surface 101 and the first recessed surface 103.

The first extending part 12 is connected to the first main part 11 and extends farther than the first inner surface 111 of the first main part 11 in the first sense of the first direction x. In the present embodiment, the first extending part 12 extends in the first sense of the first direction x from the location on the first main part 11 offset in a first sense of the second direction y. In FIG. 3, the first extending part 12 is shown with hatching.

As shown in FIGS. 3 to 5 and 7, the first extending part 12 includes a part of the first obverse surface 101, a part of the first recessed surface 103, a first-extending-part end surface 121, a first curved surface 122 and a first intermediate surface 123. The first-extending-part end surface 121 is located at the end of the first extending part 12 in the first sense of the first direction x and faces in the first sense of the first direction x. The first-extending-part end surface 121 is connected to both the first obverse surface 101 and the first recessed surface 103. In the present embodiment, the first-extending-part end surface 121 is located at the center of the semiconductor device A10 in the first direction x. The first curved surface 122 defines an inwardly curved arc as viewed in the thickness direction z. The first curved surface 122 is connected to both the first obverse surface 101 and the first recessed surface 103 and also to the first-extending-part end surface 121. The first intermediate surface 123 faces in the first sense of the first direction x. The first intermediate surface 123 is located between the first-extending-part end surface 121 and the first inner surface 111 of the first main part 11 in the first direction x. The first intermediate surface 123 is offset in a second sense of the second direction y from the first-extending-part end surface 121. The first intermediate surface 123 is connected to both the first obverse surface 101 and the first recessed surface 103 and also to the first curved surface 122.

As shown in FIGS. 3, 4 and 7, the first terminal part 13 is connected to the first main part 11 and is rectangular as viewed in the thickness direction z. The first terminal part 13 is connected to the end of the first main part 11 in the second sense of the first direction x. The length of the first terminal part 13 in the second direction y is less than the length of the first main part 11 in the second direction y. The first terminal part 13 is located at the center of the first main part 11 in the second direction y as viewed in the first direction x. The first terminal part 13 includes a part of the first obverse surface 101, a part of the first reverse surface 102 and a first end surface 131. The first end surface 131 is located at the end of the first terminal part 13 in the second sense of the first direction x and faces in the second sense of the first direction x. The first end surface 131 is exposed from the sealing resin 5.

As shown in FIGS. 3 and 8, the first connecting part 14 is connected to the first main part 11 and is rectangular as viewed in the thickness direction z. The first connecting part 14 is connected to the end of the first main part 11 in the first sense of the second direction y. The length of the first connecting part 14 in the first direction x is less than the length of the first main part 11 in the first direction x. The first connecting part 14 is located at the center of the first main part 11 in the first direction x as viewed in the second direction y. The first connecting part 14 includes a first-connecting-part end surface 141. The first-connecting-part end surface 141 is located at the end of the first connecting part 14 in the first sense of the second direction y and faces in the first sense of the second direction y. The first-connecting-part end surface 141 is exposed from the sealing resin 5.

The second connecting part 15 is connected to the first main part 11 and is rectangular as viewed in the thickness direction z. The second connecting part 15 is connected to the end of the first main part 11 in the second sense of the second direction y. The length of the second connecting part in the first direction x is less than the length of the first main part 11 in the first direction x. The second connecting part 15 is located at the center of the first main part 11 in the first direction x as viewed in the second direction y. The second connecting part 15 includes a second-connecting-part end surface 151. The second-connecting-part end surface 151 is located at the end of the second connecting part 15 in the second sense of the second direction y and faces in the second sense of the second direction y. The second-connecting-part end surface 151 is exposed from the sealing resin 5.

As shown in FIGS. 3 to 5 and 7, the second lead 2 includes a second obverse surface 201, a second reverse surface 202 and a second recessed surface 203. The second obverse surface 201 faces in the first sense of the thickness direction z. The second obverse surface 201 is at the same location as the first obverse surface 101 of the first lead 1 in the thickness direction z. The second obverse surface 201 is covered with the sealing resin 5. Each of the second reverse surface 202 and the second recessed surface 203 faces away from the second obverse surface 201 (faces in the second sense of the thickness direction z). The second reverse surface 202 is exposed from the sealing resin 5. The second recessed surface 203 is offset from the second reverse surface 202 in the first sense of the thickness direction z and hence closer than the second reverse surface 202 to the second obverse surface 201. As viewed in the thickness direction z, the second recessed surface 203 overlaps with a part of the second obverse surface 201. As viewed in the thickness direction z, the second recessed surface 203 is offset in the second sense of the first direction x from the second reverse surface 202. The second recessed surface 203 is covered with the sealing resin 5. The second recessed surface 203 is formed by half-etching, for example.

The second lead 2 includes a second main part 21, a second extending part 22, a second terminal part 23, a third connecting part 24 and a fourth connecting part 25. As shown in FIG. 3, the second main part 21 is rectangular as viewed in the thickness direction z. In FIG. 3, the second main part 21 is located on the right side (offset in the first sense of the first direction x) with respect to the center of the semiconductor device A10 in the first direction x. The first main part 11 of the first lead 1 and the second main part 21 are spaced apart from each other in the first direction x in a symmetrical layout with respect to the center of the semiconductor device A10 in the first direction x (in FIG. 3, the left part and the right part form a symmetrical layout).

As shown in FIGS. 3 to 5 and 7, the second main part 21 includes a part of the second obverse surface 201, a part of the second reverse surface 202, a part of the second recessed surface 203 and a second inner surface 211. The second obverse surface 201 corresponding to the second main part 21 is where the second semiconductor element 3B is mounted. The second reverse surface 202 corresponding to the second main part 21 serves as a reverse-surface terminal. The second inner surface 211 is located at the end of the second main part 21 in the second sense of the first direction x and faces in the second sense of the first direction x. The second inner surface 211 is connected to both the second obverse surface 201 and the second recessed surface 203.

The second extending part 22 is connected to the second main part 21 and extends farther than the second inner surface 211 of the second main part 21 in the second sense of the first direction x. In the present embodiment, the second extending part 22 extends in the second sense of the first direction x from the location on the second main part 21 offset in the second sense of the second direction y. In FIG. 3, the second extending part 22 is shown with hatching.

As shown in FIGS. 3 to 5 and 7, the second extending part 22 includes a part of the second obverse surface 201, a part of the second recessed surface 203, a second-extending-part end surface 221, a second curved surface 222 and a second intermediate surface 223. The second-extending-part end surface 221 is located at the end of the second extending part 22 in the second sense of the first direction x and faces in the second sense of the first direction x. The second-extending-part end surface 221 is connected to both the second obverse surface 201 and the second recessed surface 203. In the present embodiment, the second-extending-part end surface 221 is located at the center of the semiconductor device A10 in the first direction x. The second curved surface 222 defines an inwardly curved arc as viewed in the thickness direction z. The second curved surface 222 is connected to both the second obverse surface 201 and the second recessed surface 203 and also to the second-extending-part end surface 221. The second intermediate surface 223 faces in the second sense of the first direction x. The second intermediate surface 223 is located between the second-extending-part end surface 221 and the second inner surface 211 of the second main part 21 in the first direction x. The second intermediate surface 223 is offset in the first sense of the second direction y from the second-extending-part end surface 221. The second intermediate surface 223 is connected to both the second obverse surface 201 and the second recessed surface 203 and also to the second curved surface 222.

As shown in FIGS. 3, 4 and 7, the second terminal part 23 is connected to the second main part 21 and is rectangular as viewed in the thickness direction z. As viewed in the first direction x, the second terminal part 23 is connected to the end of the second main part 21 in the first sense of the first direction x. The length of the second terminal part 23 in the second direction y is less than the length of the second main part 21 in the second direction y. The second terminal part 23 is located at the center of the second main part 21 in the second direction y as viewed in the first direction x. The second terminal part 23 includes a part of the second obverse surface 201, a part of the second reverse surface 202 and a second end surface 231. The second end surface 231 is located at the end of the second terminal part 23 in the first sense of the first direction x and faces in the first sense of the first direction x. The second end surface 231 is exposed from the sealing resin 5.

As shown in FIGS. 3 and 9, the third connecting part 24 is connected to the second main part 21 and is rectangular as viewed in the thickness direction z. The third connecting part 24 is connected to the end of the second main part 21 in the first sense of the second direction y. The length of the third connecting part 24 in the first direction x is less than the length of the second main part 21 in the first direction x. The third connecting part 24 is located at the center of the second main part 21 in the first direction x as viewed in the second direction y. The third connecting part 24 includes a third-connecting-part end surface 241. The third-connecting-part end surface 241 is located at the end of the third connecting part 24 in the first sense of the second direction y and faces in the first sense of the second direction y. The third-connecting-part end surface 241 is exposed from the sealing resin 5.

The fourth connecting part 25 is connected to the second main part 21 and is rectangular as viewed in the thickness direction z. The fourth connecting part 25 is connected to the end of the second main part 21 in the second sense of the second direction y. The length of the fourth connecting part in the first direction x is less than the length of the second main part 21 in the first direction x. The fourth connecting part 25 is located at the center of the second main part 21 in the first direction x as viewed in the second direction y. The fourth connecting part 25 includes a fourth-connecting-part end surface 251. The fourth-connecting-part end surface 251 is located at the end of the fourth connecting part 25 in the second sense of the second direction y and faces in the second sense of the second direction y. The fourth-connecting-part end surface 251 is exposed from the sealing resin 5.

The first semiconductor element 3A and the second semiconductor element 3B provide the electrical function of the semiconductor device A10. The first semiconductor element 3A and the second semiconductor element 3B are not limited to a specific type of elements. In the present embodiment, both the first semiconductor element 3A and the second semiconductor element 3B are the same type of elements, which are Zener diodes in this example. In the present embodiment, each of the first semiconductor element 3A and the second semiconductor element 3B is rectangular as viewed in the thickness direction z.

As shown in FIGS. 3 and 7, the first semiconductor element 3A is disposed on the first obverse surface 101 of the first main part 11 (the first lead 1). The first semiconductor element 3A includes a first element side surface 301, a second element side surface 302, a third element side surface 303, a fourth element side surface 304, a first electrode 31 and a second electrode 32. Each of the first element side surface 301, the second element side surface 302, the third element side surface 303 and the fourth element side surface 304 is located between the opposite surfaces of the first semiconductor element 3A in the thickness direction z and connected to the opposite surfaces of the first semiconductor element 3A in the thickness direction z. The first element side surface 301 faces in the first sense of the first direction x. The second element side surface 302 faces in the second sense of the first direction x. The third element side surface 303 faces in the first sense of the second direction y. The fourth element side surface 304 faces in the second sense of the second direction y. The first electrode 31 is disposed on the surface of the first semiconductor element 3A facing in the first sense of the thickness direction z. The second electrode 32 is disposed on the surface of the first semiconductor element 3A facing in the second sense of the thickness direction z. In the present embodiment, the first electrode 31 is an anode (positive electrode) and the second electrode 32 is a cathode (negative electrode). The first semiconductor element 3A is electrically bonded to the first obverse surface 101 (the first main part 11, the first lead 1) via a conductive bonding material 39. The conductive bonding material 39 conductively bonds the first obverse surface 101 and the second electrode 32. The conductive bonding material 39 is not particularly limited, and may be solder, metal paste or sintered metal.

The second semiconductor element 3B is disposed on the second obverse surface 201 of the second main part 21 (the second lead 2). The second semiconductor element 3B includes a first element side surface 301, a second element side surface 302, a third element side surface 303, a fourth element side surface 304, a first electrode 31 and a second electrode 32. Each of the first element side surface 301, the second element side surface 302, the third element side surface 303 and the fourth element side surface 304 is located between the opposite surfaces of the second semiconductor element 3B in the thickness direction z and connected to the opposite surfaces of the second semiconductor element 3B in the thickness direction z. The first element side surface 301 faces in the first sense of the first direction x. The second element side surface 302 faces in the second sense of the first direction x. The third element side surface 303 faces in the first sense of the second direction y. The fourth element side surface 304 faces in the second sense of the second direction y. The first electrode 31 is disposed on the surface of the second semiconductor element 3B facing in the first sense of the thickness direction z. The second electrode 32 is disposed on the surface of the second semiconductor element 3B facing in the second sense of the thickness direction z. In the present embodiment, the first electrode 31 is an anode (positive electrode) and the second electrode 32 is a cathode (negative electrode). The second semiconductor element 3B is electrically bonded to the second obverse surface 201 (the second main part 21, the second lead 2) via a conductive bonding material 39. The conductive bonding material 39 conductively bonds the second obverse surface 201 and the second electrode 32. The conductive bonding material 39 is not particularly limited, and may be solder, metal paste or sintered metal.

The conducting member 4 electrically connects the first electrode 31 of the first semiconductor element 3A and the first electrode 31 of the second semiconductor element 3B. The conducting member 4 is not limited to a specific configuration, and a metal wire or ribbon may be used. Examples of the metal used for the conducting member 4 include gold (Au), aluminum (Al), and alloys of such metals. Although one conducting member 4 is used in the present embodiment, two or more conducting members 4 may be used in another example.

FIG. 10 is a circuit diagram of the semiconductor device A10. The first semiconductor element 3A and the second semiconductor element 3B are connected in series in opposite directions. With the configuration shown in the figure, when a voltage exceeding the breakdown voltage is applied between the first lead 1 and the second lead 2 in either direction, the combination of the first semiconductor element 3A and the second semiconductor element 3B allows a current to flow at a constant voltage.

The sealing resin 5 covers a part of the first lead 1, a part of the second lead 2, the first semiconductor element 3A, the second semiconductor element 3B and the conducting member 4. The sealing resin 5 is made of black epoxy resin, for example.

As shown in FIGS. 1 and 7 to 9, the sealing resin 5 includes a resin obverse surface 51, a resin reverse surface 52, a first resin side surface 531, a second resin side surface 532, a third resin side surface 533 and a fourth resin side surface 534. The resin obverse surface 51 and the resin reverse surface 52 are spaced apart from each other in the thickness direction z, facing away from each other. The resin obverse surface 51 faces in the first sense of the thickness direction z. The resin reverse surface 52 faces in the second sense of the thickness direction z. As shown in FIG. 7, the first reverse surface 102 of the first lead 1 and the second reverse surface 202 of the second lead 2 are exposed on the resin reverse surface 52 and flush with the resin reverse surface 52.

Each of the first resin side surface 531, the second resin side surface 532, the third resin side surface 533 and the fourth resin side surface 534 is located between the resin obverse surface 51 and the resin reverse surface 52 and connected to the resin obverse surface 51 and the resin reverse surface 52. As shown in FIG. 7, the first resin side surface 531 and the second resin side surface 532 are spaced apart from each other first direction x, facing away from each other. The first resin side surface 531 faces in the first sense of the first direction x. The second resin side surface 532 faces in the second sense of the first direction x. The second end surface 231 of the second lead 2 is exposed on the first resin side surface 531 and flush with the first resin side surface 531. The first end surface 131 of the first lead 1 is exposed on the second resin side surface 532 and flush with the second resin side surface 532.

As shown in FIGS. 8 and 9, the third resin side surface 533 and the fourth resin side surface 534 are spaced apart from each other in the second direction y, facing away from each other. The third resin side surface 533 faces in the first sense of the second direction y. The fourth resin side surface 534 faces in the second sense of the second direction y. The first-connecting-part end surface 141 of the first lead 1 and the third-connecting-part end surface 241 of the second lead 2 are exposed on the third resin side surface 533 and flush with the third resin side surface 533. The second-connecting-part end surface 151 of the first lead 1 and the fourth-connecting-part end surface 251 of the second lead 2 are exposed on the fourth resin side surface 534 and flush with the fourth resin side surface 534.

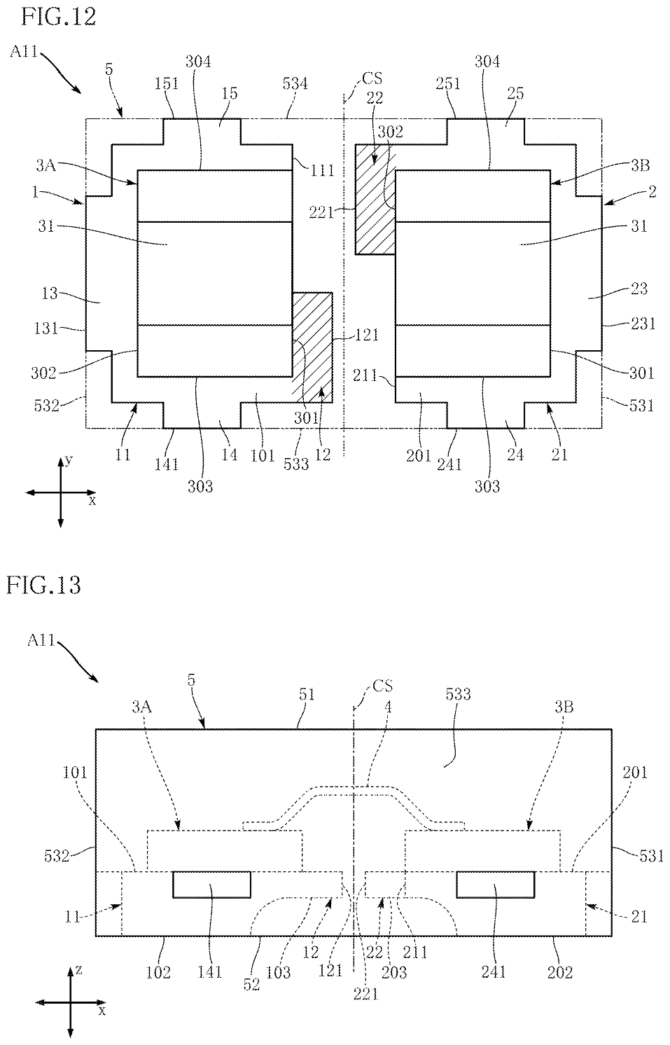

FIG. 7 and some other figures show, with dot-dash lines, a first-direction middle plane CS that is a section of the sealing resin 5 taken along a line equidistant in the first direction x from the first element side surface 301 of the first semiconductor element 3A and the second element side surface 302 of the second semiconductor element 3B. The first main part 11 of the first lead 1 is offset in the second sense of the first direction x (located on the left side in FIG. 7) with respect to the first-direction middle plane CS. The second main part 21 of the second lead 2 is offset in the first sense of the first direction x (located on the right side in FIG. 7) with respect to the first-direction middle plane CS. The first main part 11 and the second main part 21 are spaced apart from each other in the first direction x with the first-direction middle plane CS in between. As shown in FIG. 3, the first main part 11 and the second main part 21 as viewed in the thickness direction z are in a symmetrical layout with respect to the first-direction middle plane CS (in FIG. 3, the left part and the right part form a symmetrical layout). In the present embodiment, the first-extending-part end surface 121 of the first extending part 12 coincides with the first-direction middle plane CS. Also, the second-extending-part end surface 221 of the second extending part 22 coincides with the first-direction middle plane CS. Note that the expression “the first-extending-part end surface 121 (the second-extending-part end surface 221) coincides with the first-direction middle plane CS” does not require the end surface 121 (221) to perfectly coincide with the position of the first-direction middle plane CS but allows for some deviations due to the manufacturing precision of the leads 1 and 2 as well as of the sealing resin 5. This applies to the variations described later with reference to FIG. 12 and the following figures.

Next, advantages of the present embodiment will be described.

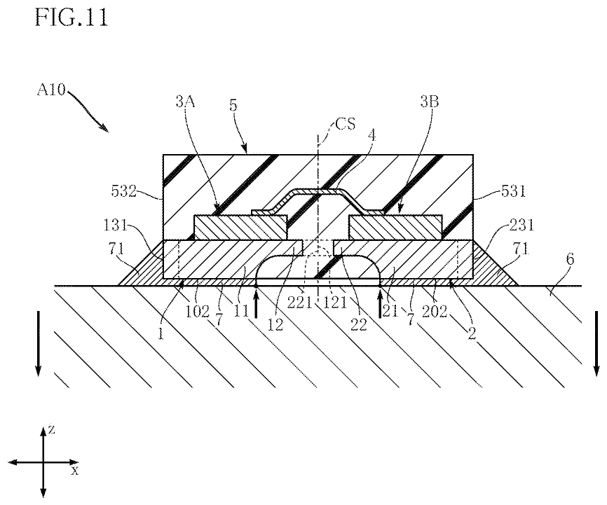

For use, the semiconductor device A10 is mounted on a circuit board by surface mounting. FIG. 11 is a sectional view of the semiconductor device A10 that is mounted on a circuit board 6. The semiconductor device A10 is bonded to the circuit wiring (not shown) formed on the circuit board 6 with solder 7. In the semiconductor device A10, the first reverse surface 102 and the second reverse surface 202 are exposed from the sealing resin 5 and bonded as the reverse-surface terminals to the circuit wiring with the solder 7. In addition, the first end surface 131 and the second end surface 231 are exposed from the sealing resin 5 as the terminals, and solder fillets 71 are formed in regions between each of the first end surface 131 and the second end surface 231 and the circuit board.

The circuit board 6 on which the semiconductor device A10 is mounted can warp due to heat and other factors. For example, the opposite ends of the circuit board 6 in the first direction x having the semiconductor device A10 in the middle may bend toward the side in the second sense of the thickness direction z (downward in FIG. 11). As a result, the sealing resin 5 is subjected to a relatively large stress, especially at a part between the first main part 11 of the first lead 1 and the second main part 21 of the second lead 2 in the first direction x.

In the semiconductor device A10, the first lead 1 includes the first extending part 12. The first extending part 12 is connected to the first main part 11, which is offset in the second sense of the first direction x with respect to the first-direction middle plane CS of the sealing resin 5, and extends in the first sense of the first direction x (toward the second main part 21). This configuration can reduce the stress applied to the part of the sealing resin 5 between the first main part 11 and the first extending part 12, preventing detachment of the sealing resin 5 from the leads 1 and 2 and other damage.

In the semiconductor device A10, the first-extending-part end surface 121 of the first extending part 12 coincides with the first-direction middle plane CS of the sealing resin That is, the first extending part 12 extends to the middle of the sealing resin 5 in the first direction x. This configuration is preferable for preventing detachment of the sealing resin 5 from the leads 1 and 2 and other damage.

In the semiconductor device A10, the second lead 2 includes the second extending part 22. The second extending part 22 is connected to the second main part 21, which is offset in the first sense of the first direction x with respect to the first-direction middle plane CS of the sealing resin 5, and extends in the second sense of the first direction x (toward the first main part 11). The second extending part 22 can further reduce the stress applied to the part of the sealing resin 5 between the second main part 21 and the second extending part 22, along with the first extending part 12 described above. The second extending part 22 can therefore effectively prevent detachment of the sealing resin 5 from the leads 1 and 2 and other damage.

In the semiconductor device A10, the second-extending-part end surface 221 of the second extending part 22 coincides with the first-direction middle plane CS of the sealing resin That is, the second extending part 22 extends to the middle of the sealing resin 5 in the first direction x. This configuration is even more preferable for preventing detachment of the sealing resin 5 from the leads 1 and 2 and other damage.

As viewed in first direction x, the first extending part 12 of the first lead 1 and the second extending part 22 of the second lead 2 are offset respectively in the first sense and the second sense of the second direction y. This arrangement of the first extending part 12 and the second extending part 22 can ensure that the first lead 1 (the first main part 11 and the first extending part 12) and the second lead 2 (the second main part 21 and the second extending part 22) are not too close to each other in the first direction x without increasing the distance between the first main part 11 and the second main part 21. The semiconductor device A10 of this configuration can be packaged to provide an increased strength without increasing the package size or decreasing the dielectric strength.

The first lead 1 includes the first recessed surface 103 facing in the second sense of the thickness direction z. Each of the first main part 11 and the first extending part 12 includes a part of the first recessed surface 103. The first recessed surface 103 is covered with the sealing resin 5. The second lead 2 includes the second recessed surface 203 facing in the second sense of the thickness direction z. Each of the second main part 21 and the second extending part 22 includes a part of the second recessed surface 203. The second recessed surface 203 is covered with the sealing resin 5. This configuration is preferable for preventing unintentional detachment of the first lead 1 (the first main part 11 and the first extending part 12) and the second lead 2 (the second main part 21 and the second extending part 22) from the resin reverse surface 52 (the sealing resin 5). This consequently maintains the bonding of the respective second electrodes 32 to the first obverse surface 101 and the second obverse surface 201.

The first semiconductor element 3A disposed on the first obverse surface 101 (the first main part 11) and the second semiconductor element 3B disposed on the second obverse surface 201 (the second main part 21) are the same type of elements (Zener diodes). For this reason, the first main part 11 and the second main part 21 for supporting the first semiconductor element 3A and the second semiconductor element 3B are preferably arranged in a symmetrical layout as viewed in the thickness direction z with respect to the first-direction middle plane CS of the sealing resin 5 (in FIG. 3, the left part and the right part form a symmetrical layout). In the semiconductor device A10, the respective first electrodes 31 of the semiconductor elements 3A and 3B are electrically connected together by the conducting member 4. In contrast, the first extending part 12 and the second extending part 22 located between the first main part 11 and the second main part 21 are not connected to any conducting member (such as a wire) and hence not a part of an electrical conduction path. Providing the first extending part 12 and the second extending part 22 between the first main part 11 and the second main part 21 can improve the strength of the semiconductor device A10 when packaged.

FIGS. 12 and 13 show a semiconductor device according to a first variation of the first embodiment. FIG. 12 is a plan view similar to FIG. 3 of the first embodiment. FIG. 13 is a front view of the semiconductor device shown in FIG. 12. In FIG. 12 and the following figures, the same or similar elements as those of the semiconductor device A10 of the above embodiment are denoted by the same reference signs.

A semiconductor device All of this variation differs from the semiconductor device A10 in the shape of the first extending part 12 and the second extending part 22. Each of the first extending part 12 and the second extending part 22 of this variation is rectangular as viewed in the thickness direction z. The first extending part 12 includes a part of the first obverse surface 101, a part of the first recessed surface 103 and a first-extending-part end surface 121. The first-extending-part end surface 121 is offset in the second sense of the first direction x (located on the left side in FIG. 12) with respect to the first-direction middle plane CS of the sealing resin 5. The second extending part 22 includes a part of the second obverse surface 201, a part of the second recessed surface 203 and a second-extending-part end surface 221. The second-extending-part end surface 221 is offset in the first sense of the first direction x (located on the right side in FIG. 12) with respect to the first-direction middle plane CS of the sealing resin 5.

In the semiconductor device All of this variation, the first lead 1 includes a first extending part 12. The first extending part 12 is connected to the first main part 11, which is offset in the second sense of the first direction x with respect to the first-direction middle plane CS of the sealing resin 5, and extends in the first sense of the first direction x (toward the second main part 21). With this configuration, even if warping occurs in the circuit board on which the semiconductor device All is mounted, a region of the sealing resin 5 that will be subjected to a significant stress is reduced between the first main part 11 and the first extending part 12. This consequently prevents detachment of the sealing resin 5 from the leads 1 and 2 and other damage. The semiconductor device All has a configuration in common with the semiconductor device A10 and therefore achieves the same effect as that achieved by the common configuration in the first embodiment.

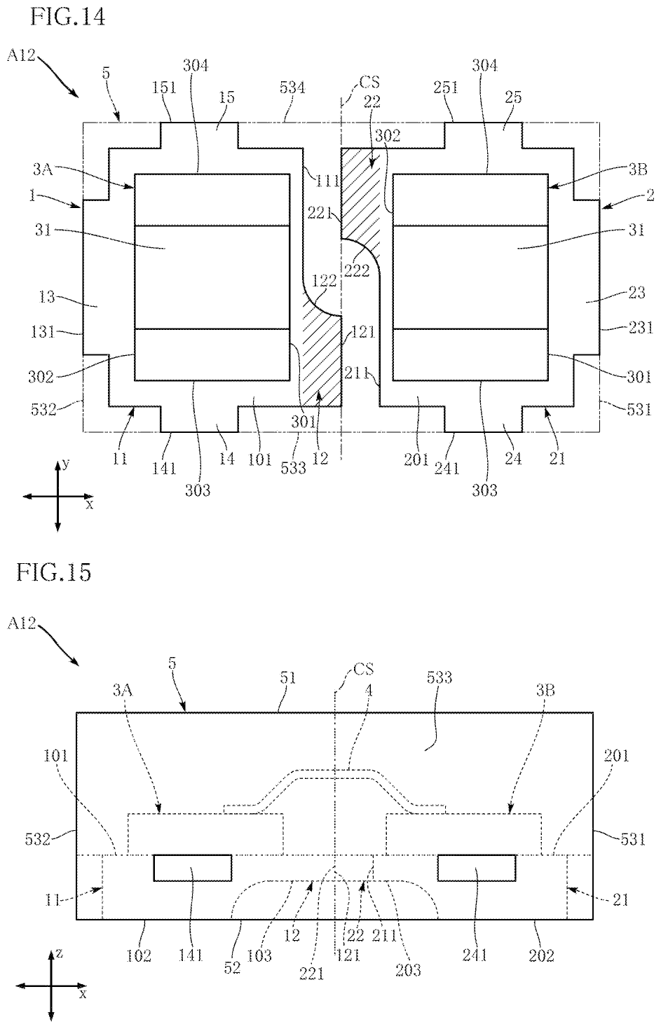

FIGS. 14 and 15 show a semiconductor device according to a second variation of the first embodiment. FIG. 14 is a plan view similar to FIG. 3 of the first embodiment. FIG. 15 is a front view of the semiconductor device shown in FIG. 14. A semiconductor device A12 of this variation differs from the semiconductor device A10 in the shape of the first extending part 12 and the second extending part 22. In this variation, the first extending part 12 and the second extending part 22 do not include the first intermediate surface 123 and the second intermediate surface 223 and have a shape defined by a combination of a rectangular part and a recessed part as viewed in the thickness direction z. The first extending part 12 includes a part of the first obverse surface 101, a part of the first recessed surface 103, a first-extending-part end surface 121 and a first curved surface 122. The first-extending-part end surface 121 coincides with the first-direction middle plane CS of the sealing resin 5. The second extending part 22 includes a part of the second obverse surface 201, a part of the second recessed surface 203, a second-extending-part end surface 221 and a second curved surface 222. The second-extending-part end surface 221 coincides with the first-direction middle plane CS of the sealing resin 5.

In the semiconductor device A12 of this variation, the first lead 1 includes a first extending part 12. The first extending part 12 of this variation is connected to the first main part 11, which is offset in the second sense of the first direction x with respect to the first-direction middle plane CS of the sealing resin 5, and extends in the first sense of the first direction x (toward the second main part 21). With this configuration, even if warping occurs in the circuit board on which the semiconductor device All is mounted, a region of the sealing resin 5 that will be subjected to a significant stress is reduced between the first main part 11 and the first extending part 12. This consequently prevents detachment of the sealing resin 5 from the leads 1 and 2 and other damage. The semiconductor device A12 has a configuration in common with the semiconductor device A10 and therefore achieves the same effect as that achieved by the common configuration in the first embodiment.

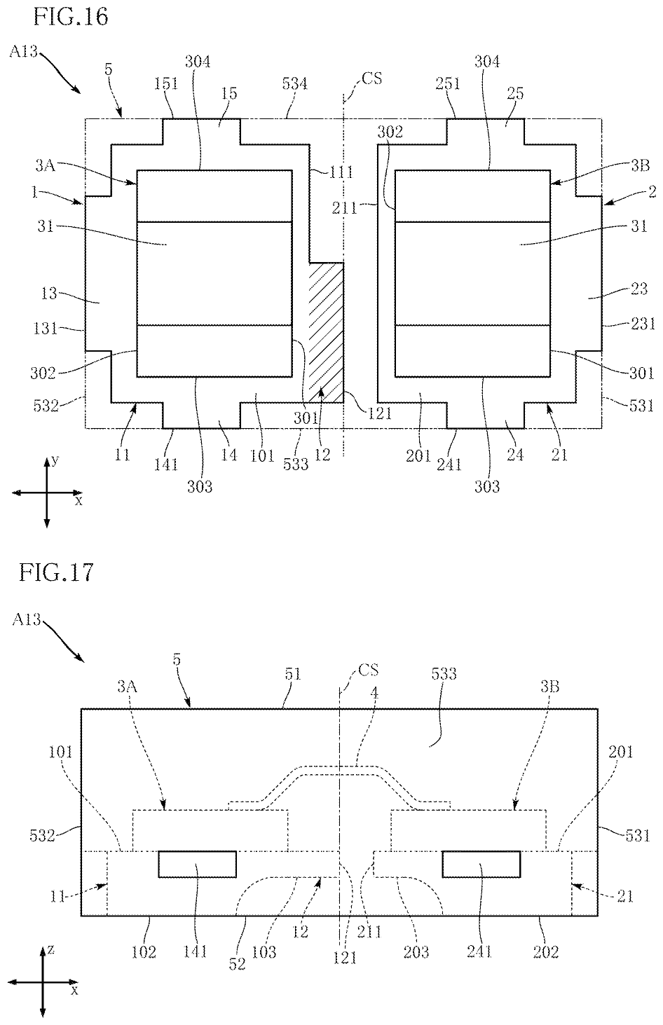

FIGS. 16 and 17 show a semiconductor device according to a third variation of the first embodiment. FIG. 16 is a plan view similar to FIG. 3 of the first embodiment. FIG. 17 is a front view of the semiconductor device shown in FIG. 16.

A semiconductor device A13 of this variation differs from the semiconductor device A10 in the shape of the first extending part 12. Unlike the semiconductor device A10, in addition, the semiconductor device A13 does not include the second extending part 22. The first extending part 12 of this variation is rectangular as viewed in the thickness direction z. The first extending part 12 includes a part of the first obverse surface 101, a part of the first recessed surface 103 and a first-extending-part end surface 121. The first-extending-part end surface 121 coincides with the first-direction middle plane CS of the sealing resin 5.

The semiconductor device A13 has a configuration in common with the semiconductor device A10 and therefore achieves the same effect as that achieved by the common configuration in the first embodiment.

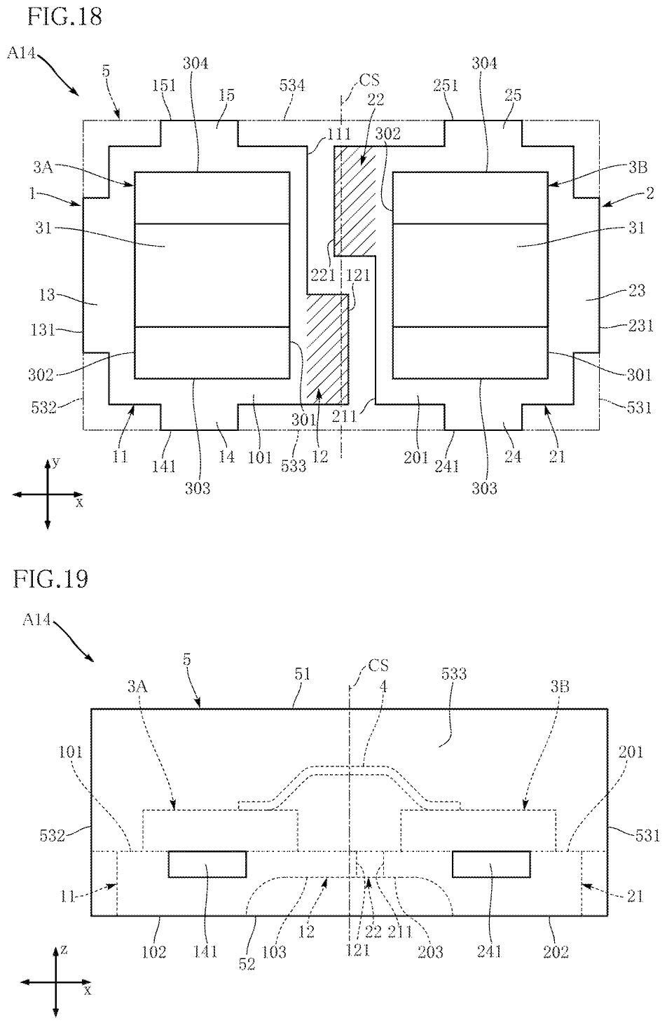

FIGS. 18 and 19 show a semiconductor device according to a fourth variation of the first embodiment. FIG. 18 is a plan view similar to FIG. 3 of the first embodiment. FIG. 19 is a front view of the semiconductor device shown in FIG. 18.

A semiconductor device A14 of this variation differs from the semiconductor device A10 in the shape of the first extending part 12 and the second extending part 22. The first extending part 12 and the second extending part 22 of this variation are rectangular as viewed in the thickness direction z. The first extending part 12 includes a part of the first obverse surface 101, a part of the first recessed surface 103 and a first-extending-part end surface 121. The first-extending-part end surface 121 is offset in the first sense of the first direction x (located on the right side in FIG. 18) with respect to the first-direction middle plane CS of the sealing resin 5. The second extending part 22 includes a part of the second obverse surface 201, a part of the second recessed surface 203 and a second-extending-part end surface 221. The second-extending-part end surface 221 is offset in the second sense of the first direction x (located on the left side in FIG. 18) with respect to the first-direction middle plane CS of the sealing resin 5.

The semiconductor device A14 has a configuration in common with the semiconductor device A10 and therefore achieves the same effect as that achieved by the common configuration in the first embodiment.

In the semiconductor device A14, the first extending part 12 is connected to the first main part 11, which is offset in the second sense of the first direction x with respect to the first-direction middle plane CS, and extends in the first sense of the first direction x beyond the first-direction middle plane CS. The second extending part 22 is connected to the second main part 21, which is offset in the first sense of the first direction x with respect to the first-direction middle plane CS, and extends in the second sense of the first direction x beyond the first-direction middle plane CS. The semiconductor device A14 of this configuration can be packaged to provide an increased strength.

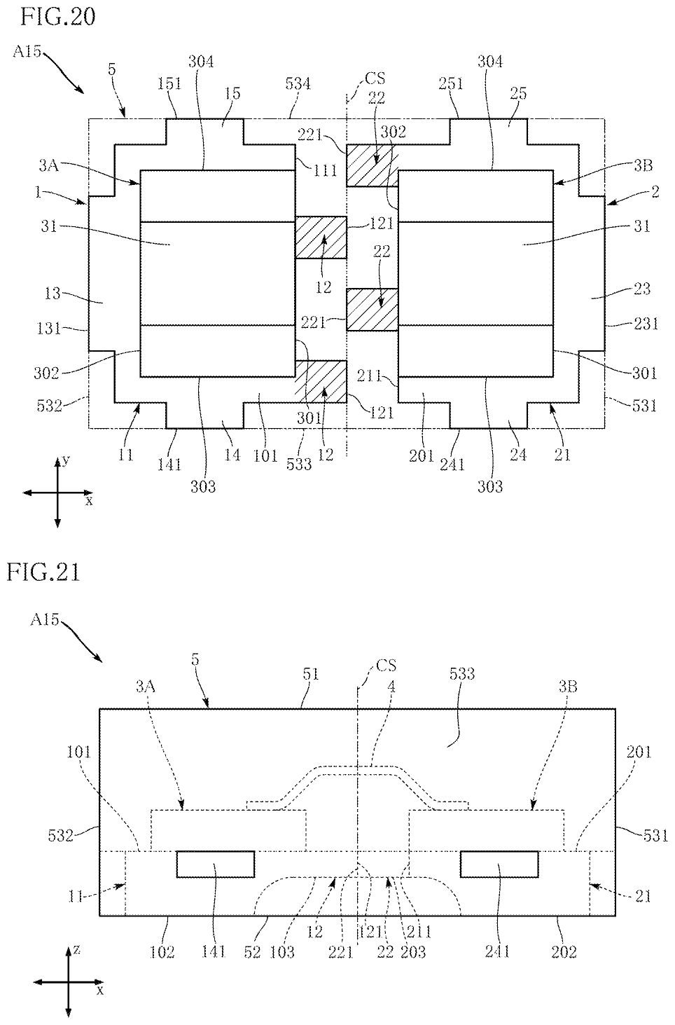

FIGS. 20 and 21 show a semiconductor device according to a fifth variation of the first embodiment. FIG. 20 is a plan view similar to FIG. 3 of the first embodiment. FIG. 21 is a front view of the semiconductor device shown in FIG. 20.

A semiconductor device A15 of this variation differs from the semiconductor device A10 in the shape and the arrangement of the first extending part 12 and the second extending part 22. In this variation, the first lead 1 includes a plurality of (two in the illustrated example) first extending parts 12. The second lead 2 includes a plurality of (two in the illustrated example) second extending parts 22. Each of the first extending parts 12 and the second extending parts 22 is rectangular as viewed in the thickness direction z. As viewed in the first direction x, the first extending parts 12 and the second extending parts 22 are alternately arranged along the second direction y. Each first extending part 12 includes a part of the first obverse surface 101, a part of the first recessed surface 103 and a first-extending-part end surface 121. The respective first-extending-part end surfaces 121 coincide with the first-direction middle plane CS of the sealing resin 5. Each second extending part 22 includes a part of the second obverse surface 201, a part of the second recessed surface 203 and a second-extending-part end surface 221. The respective second-extending-part end surfaces 221 coincide with the first-direction middle plane CS of the sealing resin 5.

The semiconductor device A15 has a configuration in common with the semiconductor device A10 and therefore achieves the same effect as that achieved by the common configuration in the first embodiment.

The semiconductor devices according to the present disclosure are not limited to those described above. Various design changes can be made to the specific configuration of each part of the semiconductor devices according to the present disclosure.

For example, although the semiconductor device A10 described in the first embodiment and their variations are provided in QFN packages, the packaging of the semiconductor device is not limited to QFN. The semiconductor devices of the present disclosure may be provided in QFP (quad flat packages) with leads extending from the side surfaces of the sealing resin.

In addition, although the above embodiment describes the first reverse surface 102 of the first main part 11 and the second reverse surface 202 of the second main part 21 exposed on the sealing resin 5 and used as reverse-surface terminals, this is merely one example. In another configuration, the first reverse surface 102 and the second reverse surface 202 are not used as reverse-surface terminals.

The present disclosure includes the embodiments described in the following clauses.

Clause 1. A semiconductor device comprising:
a first lead including a first obverse surface and a first reverse surface respectively facing in a first sense and a second sense of a thickness direction;
a second lead including a second obverse surface and a second reverse surface respectively facing in the first sense and the second sense of the thickness direction, the second lead being spaced apart from the first lead in a first sense of a first direction orthogonal to the thickness direction;
a first semiconductor element disposed on the first obverse surface, and a second semiconductor element disposed on the second obverse surface; and
a sealing resin covering a part of the first lead, a part of the second lead, the first semiconductor element and the second semiconductor element,
wherein the first semiconductor element includes a first element side surface facing in the first sense of the first direction, and the second semiconductor element includes a second element side surface facing in a second sense of the first direction,
the first lead includes: a first main part offset in the second sense of the first direction with respect to a first-direction middle plane of the sealing resin, the first-direction middle plane being equidistant in the first direction from the first element side surface of the first semiconductor element and the second element side surface of the second semiconductor element; and a first extending part extending from the first main part in the first sense of the first direction, and
the second lead includes a second main part offset in the first sense of the first direction with respect to the first-direction middle plane.

Clause 2. The semiconductor device according to Clause 1, wherein the first extending part includes a first end surface facing in the first sense of the first direction, and
the first end surface coincides with the first-direction middle plane or is offset in the first sense of the first direction with respect to the first-direction middle plane.

Clause 3. The semiconductor device according to Clause 1 or 2, wherein the first main part includes a first inner surface facing in the first sense of the first direction, and
the first extending part extends farther than the first inner surface in the first sense of the first direction.

Clause 4. The semiconductor device according to any one of Clauses 1 to 3, wherein the second lead includes a second extending part extending from the second main part in the second sense of the first direction.

Clause 5. The semiconductor device according to Clause 4, wherein the second extending part includes a second end surface facing in the second sense of the first direction, and
the second end surface coincides with the first-direction middle plane or is offset in the second sense of the first direction with respect to the first-direction middle plane.

Clause 6. The semiconductor device according to Clause 4 or 5, wherein the second main part includes a second inner surface facing in the second sense of the first direction, and
the second extending part extends farther than the second inner surface in the second sense of the first direction.

Clause 7. The semiconductor device according to Clause 6, wherein as viewed in the first direction, the first extending part and the second extending part are offset respectively in a first sense and a second sense of a second direction orthogonal to both the thickness direction and the first direction.

Clause 8. The semiconductor device according to Clause 7, wherein the first extending part includes a first intermediate surface facing in the first sense of the first direction and located between the first end surface and the first inner surface in the first direction, and
the second extending part includes a second intermediate surface facing in the second sense of the first direction and located between the second end surface and the second intermediate surface in the first direction.

Clause 9. The semiconductor device according to Clause 8, wherein the first intermediate surface is offset in the second sense of the second direction from the first end surface, and
the second intermediate surface is offset in the first sense of the second direction from the second end surface.

Clause 10. The semiconductor device according to any one of Clauses 7 to 9, wherein the first obverse surface and the second obverse surface are at a same location in the thickness direction.

Clause 11. The semiconductor device according to any one of Clauses 1 to 10, wherein the first reverse surface and the second reverse surface are exposed from the sealing resin.

Clause 12. The semiconductor device according to Clause 11, wherein as viewed in the thickness direction, the first main part and the second main part are arranged in a symmetrical layout with respect to the first-direction middle plane.

Clause 13. The semiconductor device according to Clause 12, wherein the first lead includes a first recessed surface facing in the second sense of the thickness direction and covered with the sealing resin,
the first main part includes a part of the first obverse surface, a part of the first recessed surface and at least a part of the first reverse surface, and
the first extending part includes a part of the first obverse surface and a part of the first recessed surface.

Clause 14. The semiconductor device according to Clause 13, wherein the second lead includes a second recessed surface facing in the second sense of the thickness direction and covered with the sealing resin, and
the second main part includes a part of the second obverse surface, a part of the second recessed surface and at least a part of the second reverse surface, and
the second extending part includes a part of the second obverse surface and a part of the second recessed surface.

Clause 15. The semiconductor device according to any one of Clauses 12 to 14, wherein each of the first semiconductor element and the second semiconductor element comprises an element of a same type.

Clause 16. The semiconductor device according to Clause wherein each of the first semiconductor element and the second semiconductor element is a Zener diode.

### REFERENCE SIGNS

A10, A11, A12, A13, A14, A15: Semiconductor device
1: First Lead 101: First Obverse Surface
102: First reverse surface 103: First recessed surface
11: First main part 111: First inner surface
12: First extending part 121: First end surface
122: First curved surface 123: First intermediate surface
13: First terminal part 131: First end surface
14: First connecting part
141: First-connecting-part end surface
15: Second connecting part
151: Second-connecting-part end surface
2: Second lead 201: Second obverse surface
202: Second reverse surface 203: Second recessed surface
21: Second main part 211: Second inner surface
22: Second extending part 221: Second end surface
222: Second curved surface 223: Second intermediate surface
24: Third connecting part
241: Third-connecting-part end surface
25: Fourth connecting part
251: Fourth-connecting-part end surface
3A: First semiconductor element
3B: Second semiconductor element
301: First element side surface
302: Second element side surface
303: Third element side surface
304: Fourth element side surface
31: First electrode 32: Second electrode
39: Conductive bonding material 4: Conducting member
5: Sealing resin 51: Resin obverse surface
52: Resin reverse surface 531: First resin side surface
532: Second resin side surface 533: Third resin side surface
534: Fourth resin side surface 6: Circuit board
7: Solder 71: Solder fillet
CS: First-direction middle plane x: First direction
y: Second direction z: Thickness direction

1. A semiconductor device comprising:
a first lead including a first obverse surface and a first reverse surface respectively facing in a first sense and a second sense of a thickness direction;
a second lead including a second obverse surface and a second reverse surface respectively facing in the first sense and the second sense of the thickness direction, the second lead being spaced apart from the first lead in a first sense of a first direction orthogonal to the thickness direction;
a first semiconductor element disposed on the first obverse surface, and a second semiconductor element disposed on the second obverse surface; and
a sealing resin covering a part of the first lead, a part of the second lead, the first semiconductor element and the second semiconductor element,
wherein the first semiconductor element includes a first element side surface facing in the first sense of the first direction, and the second semiconductor element includes a second element side surface facing in a second sense of the first direction,
the first lead includes: a first main part offset in the second sense of the first direction with respect to a first-direction middle plane of the sealing resin, the first-direction middle plane being equidistant in the first direction from the first element side surface of the first semiconductor element and the second element side surface of the second semiconductor element; and a first extending part extending from the first main part in the first sense of the first direction, and
the second lead includes a second main part offset in the first sense of the first direction with respect to the first-direction middle plane.

2. The semiconductor device according to claim 1, wherein the first extending part includes a first end surface facing in the first sense of the first direction, and
the first end surface coincides with the first-direction middle plane or is offset in the first sense of the first direction with respect to the first-direction middle plane.

3. The semiconductor device according to claim 1, wherein the first main part includes a first inner surface facing in the first sense of the first direction, and
the first extending part extends farther than the first inner surface in the first sense of the first direction.

4. The semiconductor device according to claim 1, wherein the second lead includes a second extending part extending from the second main part in the second sense of the first direction.

5. The semiconductor device according to claim 4, wherein the second extending part includes a second end surface facing in the second sense of the first direction, and
the second end surface coincides with the first-direction middle plane or is offset in the second sense of the first direction with respect to the first-direction middle plane.

6. The semiconductor device according to claim 4, wherein the second main part includes a second inner surface facing in the second sense of the first direction, and
the second extending part extends farther than the second inner surface in the second sense of the first direction.

7. The semiconductor device according to claim 6, wherein as viewed in the first direction, the first extending part and the second extending part are offset respectively in a first sense and a second sense of a second direction orthogonal to both the thickness direction and the first direction.

8. The semiconductor device according to claim 7, wherein the first extending part includes a first intermediate surface facing in the first sense of the first direction and located between the first end surface and the first inner surface in the first direction, and
the second extending part includes a second intermediate surface facing in the second sense of the first direction and located between the second end surface and the second intermediate surface in the first direction.

9. The semiconductor device according to claim 8, wherein the first intermediate surface is offset in the second sense of the second direction from the first end surface, and the second intermediate surface is offset in the first sense of the second direction from the second end surface.

10. The semiconductor device according to claim 7, wherein the first obverse surface and the second obverse surface are at a same location in the thickness direction.

11. The semiconductor device according to claim 1, wherein the first reverse surface and the second reverse surface are exposed from the sealing resin.

12. The semiconductor device according to claim 11, wherein as viewed in the thickness direction, the first main part and the second main part are arranged in a symmetrical layout with respect to the first-direction middle plane.

13. The semiconductor device according to claim 12, wherein the first lead includes a first recessed surface facing in the second sense of the thickness direction and covered with the sealing resin,
the first main part includes a part of the first obverse surface, a part of the first recessed surface and at least a part of the first reverse surface, and
the first extending part includes a part of the first obverse surface and a part of the first recessed surface.

14. The semiconductor device according to claim 13, wherein the second lead includes a second recessed surface facing in the second sense of the thickness direction and covered with the sealing resin, and
the second main part includes a part of the second obverse surface, a part of the second recessed surface and at least a part of the second reverse surface, and
the second extending part includes a part of the second obverse surface and a part of the second recessed surface.

15. The semiconductor device according to claim 12, wherein each of the first semiconductor element and the second semiconductor element comprises an element of a same type.

16. The semiconductor device according to claim 15, wherein each of the first semiconductor element and the second semiconductor element is a Zener diode.
